(19) United States
(12) Patent Application Publication
(10) Pub. No.: US 2024/0264529 A1
(43) Pub. Date: Aug. 8, 2024

(54) INFORMATION PROCESSING METHOD FOR DECIDING ARRANGEMENT OF DROPLETS IN FILM FORMATION

(71) Applicant: CANON KABUSHIKI KAISHA, Tokyo (JP)

(72) Inventors: NAOKI KIYOHARA, Richmond (GB); SENTARO AIHARA, Tochigi (JP); YUICHIRO OGUCHI, Tokyo (JP)

(21) Appl. No.: 18/432,445

(22) Filed: Feb. 5, 2024

(30) Foreign Application Priority Data
Feb. 8, 2023 (JP) 2023-017825

(51) Int. Cl. G03F 7/16; G03F 7/00; G03F 9/00

(52) U.S. Cl. CPC G03F 7/161; G03F 7/0002; G03F 9/7042

(57) ABSTRACT

An information processing method is applied to a film forming method of forming a cured film by arranging a plurality of droplets of a curable composition on a substrate and curing a liquid film formed by connecting the plurality of droplets. The method is of deciding an arrangement of the plurality of droplets in the film forming method, and includes updating the arrangement of the plurality of droplets until an evaluation result of the arrangement of the plurality of droplets satisfies an end condition while evaluating the arrangement of the plurality of droplets using a learned model that receives the arrangement of the plurality of droplets and outputs an evaluation value of the arrangement of the plurality of droplets.

### BACKGROUND OF THE INVENTION

### Field of the Invention

The present invention relates to an information processing for deciding arrangement of droplets in film formation.

### Description of the Related Art

There is provided a film forming method of forming a film made of a cured product of a curable composition on a substrate by arranging the curable composition on the substrate, bringing the curable composition and a mold into contact with each other, and curing the curable composition. Such film forming method can be applied to an imprint method, a planarization method, and the like. In the imprint method, by using a mold having a pattern, the pattern of the mold is transferred to a curable composition on a substrate. In the planarization method, by using a mold having a flat surface, a film having a flat upper surface is formed by bringing a curable composition on a substrate and the flat surface into contact with each other and curing the curable composition.

The curable composition is arranged in the form of droplets on the substrate. After that, the mold is pressed against the plurality of droplets of the curable composition on the substrate. This spreads the plurality of droplets to form a film of the curable composition. In this process, it can be required to form a film of the curable composition with a uniform thickness and to include no bubble in the film. The arrangement of the plurality of droplets can be adjusted in accordance with the pattern of the mold and a target film thickness. US-2004-0065976 describes a method of dividing a mold into local regions and generating a droplet arrangement pattern based on pattern density information for each divided region.

In a method of forming a film by arranging a plurality of droplets of a curable composition on a substrate and merging the plurality of droplets, it is necessary to consider the behaviors of the plurality of droplets to decrease bubbles in the film. This is because bubbles are formed when a gas is surrounded by some droplets, and thus the interaction between the droplets of whether adjacent droplets are merged influences a bubble size. The interaction between the droplets can be calculated by a physical simulation such as a fluid simulation. However, in a case where the arrangement of droplets is decided using a computer, it is necessary to repeat calculation until target specifications are satisfied. If a physical simulation is used in repeating calculation, an enormous calculation time is required.

### SUMMARY OF THE INVENTION

The present invention provides a technique advantageous in deciding the arrangement of a curable composition with a less calculation load.

One of aspects of the present invention provides an information processing method, applied to a film forming method of forming a cured film by arranging a plurality of droplets of a curable composition on a substrate and curing a liquid film formed by connecting the plurality of droplets, of deciding an arrangement of the plurality of droplets in the film forming method, comprising: updating the arrangement of the plurality of droplets until an evaluation result of the arrangement of the plurality of droplets satisfies an end condition while evaluating the arrangement of the plurality of droplets using a learned model that receives the arrangement of the plurality of droplets and outputs an evaluation value of the arrangement of the plurality of droplets.

Further features of the present invention will become apparent from the following description of exemplary embodiments with reference to the attached drawings.

### BRIEF DESCRIPTION OF THE DRAWINGS

FIG. 1A is a view exemplifying the arrangement and operation of an imprint apparatus as an example of a film forming apparatus;

FIG. 1B is a view for explaining a deformation mechanism in the imprint apparatus shown in FIG. 1A;

FIGS. 2A to 2F are views each showing a state in which an imprint material (curable composition) spreads;

FIG. 3 is a view exemplifying a system related to generation of droplet arrangement information;

FIG. 4 is a block diagram exemplifying the hardware arrangement of an optimization server (information processing apparatus);

FIG. 5 is a flowchart of an information processing method of generating a learned model using measurement data;

FIG. 6 is a view for explaining a method of generating learning data (supervised data) using the measurement data;

FIG. 7 is a view showing an overview of the information processing method of generating the learned model using the measurement data;

FIG. 8 is a flowchart of an information processing method of generating a learned model using prediction data;

FIG. 9 is a view for explaining a method of generating learning data (supervised data) using the prediction data;

FIG. 10 is a view showing an overview of the information processing method of generating the learned model using the prediction data;

FIG. 11 is a flowchart of an information processing method of generating droplet arrangement information;

FIGS. 12A and 12B are views for explaining optimization of droplet arrangement information (droplet arrangement pattern);

FIG. 13 is a view for explaining an objective function;

FIGS. 14A to 14D are views for explaining the objective function;

FIG. 15 is a view showing an overview of a process of predicting a merging probability pᵢⱼ included in the objective function by machine learning;

FIG. 16 is a view for explaining an update step of the droplet arrangement information (droplet arrangement pattern);

FIG. 17 is a view exemplifying a film thickness distribution that can depend on the droplet arrangement information (droplet arrangement pattern);

FIG. 18 is a flowchart of an information processing method of generating droplet arrangement information; and

FIGS. 19A to 19F are views exemplifying an article manufacturing method.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

An embodiment of the present disclosure will exemplarily be described below with reference to the accompanying drawings.

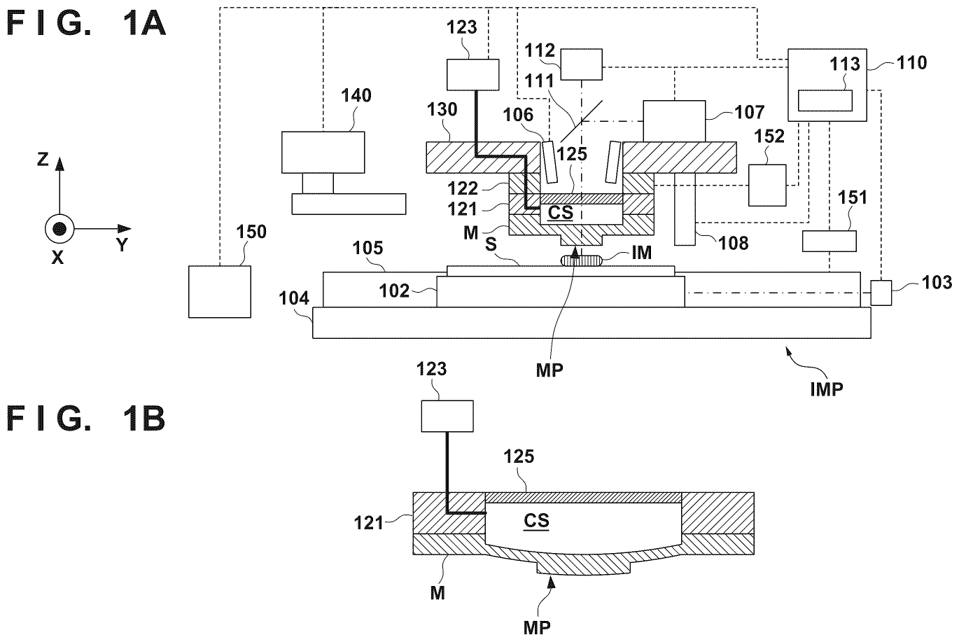

FIG. 1A shows the arrangement of an imprint apparatus IMP as an example of a film forming apparatus. The imprint apparatus IMP performs an imprint process of bringing droplets of an imprint material IM on a substrate S and a pattern region MP of a mold M into contact with each other, curing the imprint material IM, and separating the cured product of the imprint material IM and the mold M from each other. With this imprint process, a pattern made of the cured product of the imprint material IM is formed on the substrate S.

As the imprint material IM, a curable composition (to be also referred to as a resin in an uncured state) to be cured by receiving curing energy is used. As the curing energy, an electromagnetic wave or heat can be used. The electromagnetic wave can be, for example, light selected from the wavelength range of 10 nm (inclusive) to 1 mm (inclusive), for example, infrared rays, visible light, or ultraviolet light. The curable composition can be a composition cured by light irradiation or heating. Among these, a photo-curable composition cured by light irradiation contains at least a polymerizable compound and a photopolymerization initiator, and may further contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component. The imprint material can be arranged on the substrate in the form of droplets or in the form of an island or film formed by connecting a plurality of droplets. The viscosity (the viscosity at 25° C.) of the imprint material can be, for example, from 1 mPa's (inclusive) to 100 mPa·s (inclusive). As the material of the substrate, glass, ceramic, a metal, a semiconductor, a resin, or the like can be used. A member made of a material different from that of the substrate may be formed on the surface of the substrate, as needed. The substrate is, for example, a silicon wafer, a semiconductor compound wafer, or silica glass.

In the specification and the accompanying drawings, directions will be indicated on an XYZ coordinate system in which directions parallel to the surface of the substrate S are defined as the X-Y plane. Directions parallel to the X-axis, the Y-axis, and the Z-axis of the XYZ coordinate system are the X direction, the Y direction, and the Z direction, respectively. A rotation about the X-axis, a rotation about the Y-axis, and a rotation about the Z-axis are θX, θY, and θZ, respectively. Control or driving concerning the X-axis, the Y-axis, and the Z-axis means control or driving concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively. In addition, a position is information that can be specified based on coordinates on the X-, Y-, and Z-axes, and a posture is information that can be specified by values on the θX-, θY-, and θZ-axes. Positioning means controlling the position and/or posture. Alignment can include controlling the position and/or posture of at least one of the substrate and the mold.

The imprint apparatus IMP can include a substrate holding unit 102 that holds the substrate S, a substrate driving mechanism 105 that drives the substrate S by driving the substrate holding unit 102, a base 104 that supports the substrate holding unit 102, and a position measuring unit 103 that measures the position of the substrate holding unit 102. The substrate driving mechanism 105 can include, for example, a motor such as a linear motor. The imprint apparatus IMP can include a sensor 151 that detects a substrate driving force (alignment load) necessary for the substrate driving mechanism 105 to drive the substrate S (substrate holding unit 102) in alignment. The substrate driving force in alignment that is performed in a state in which the imprint material on the substrate S and the pattern region MP of the mold M are in contact with each other corresponds to a shearing force that acts between the substrate S and the mold M. The shearing force is mainly a force that acts on the substrate S and the mold Min a plane direction. The substrate driving force in alignment is, for example, correlated with the magnitude of a current supplied to the motor of the substrate driving mechanism 105 in alignment, and the sensor 151 can detect the substrate driving force based on the magnitude of the current. The sensor 151 is an example of a sensor configured to measure the influence (shearing force) received by the mold M during pattern formation.

The imprint apparatus IMP can include a mold holding unit 121 that holds the mold M, a mold driving mechanism 122 that drives the mold M by driving the mold holding unit 121, and a support structure 130 that supports the mold driving mechanism 122. The mold driving mechanism 122 can include, for example, a motor such as a voice coil motor. The imprint apparatus IMP can include a sensor 152 that detects a mold separation force (separation load) and/or a pressing force. The mold separation force is a force necessary for separating the cured product of the imprint material IM on the substrate S and the mold M from each other. The pressing force is a force for pressing the mold M to make the mold M contact the imprint material IM on the substrate S. The mold separation force and the pressing force are forces that mainly act in a direction perpendicular to the plane direction of the substrate S and the mold M. The mold separation force and the pressing force are, for example, correlated with the magnitude of a current supplied to the motor of the mold driving mechanism 122, and the sensor 152 can detect the mold separation force and the pressing force based on the magnitude of the current. The sensor 152 is an example of a sensor configured to measure the influence (mold separation force and/or pressing force) received by the mold M during pattern formation.

The substrate driving mechanism 105 and the mold driving mechanism 122 form a driving mechanism for adjusting a relative position and a relative posture between the substrate S and the mold M. The adjustment of the relative position between the substrate S and the mold M by the driving mechanism includes driving to bring the mold into contact with the imprint material on the substrate S and separate the mold from the cured imprint material (a pattern made of the cured product). The substrate driving mechanism 105 can be configured to drive the substrate S with respect to a plurality of axes (for example, three axes including the X-axis, the Y-axis, and the θZ-axis, and preferably, six axes including the X-axis, the Y-axis, the Z-axis, the θX-axis, the θY-axis, and the θZ-axis). The mold driving mechanism 122 can be configured to drive the mold M with respect to a plurality of axes (for example, three axes including the Z-axis, the θX-axis, and the θY-axis, and preferably, six axes including the X-axis, the Y-axis, the Z-axis, the θX-axis, the θY-axis, and the θZ-axis).

The imprint apparatus IMP can include a mold conveyance mechanism 140 that conveys the mold M, and a mold cleaner 150. The mold conveyance mechanism 140 can be configured to, for example, convey the mold M to the mold holding unit 121 and convey the mold M from the mold holding unit 121 to an original stocker (not shown) or the mold cleaner 150. The mold cleaner 150 cleans the mold M using UV light, a chemical solution, and the like.

The mold holding unit 121 can include a window member 125 configured to form a pressure control space CS on the side of the back surface of the mold M (the surface opposite to the pattern region MP where the pattern to be transferred to the substrate S is formed). The imprint apparatus IMP can include a deformation mechanism 123 configured to deform the pattern region MP of the mold M in a convex shape toward the substrate S, as schematically shown in FIG. 1B, by controlling the pressure (to be referred to as a cavity pressure hereinafter) in the pressure control space CS. Furthermore, the imprint apparatus IMP can include an alignment measuring device 106, a curing unit 107, an image capturing unit 112, and an optical member 111. The alignment measuring device 106 illuminates an alignment mask on the substrate S and an alignment mark on the mold M and captures images of these alignment marks, thereby measuring the relative position between the marks. The imprint apparatus IMP includes a plurality of alignment measuring devices 106, and can simultaneously observe a plurality of alignment marks formed on the shot region of the substrate S and the mold M. For example, the imprint apparatus IMP includes four alignment measuring devices 106 that observe alignment marks formed at the four corners of each of the shot region of the substrate S and the mold M. The alignment measuring device 106 can be positioned by a driving mechanism (not shown) in accordance with the positions of alignment marks to be observed. An image captured by the alignment measuring device 106 will be referred to as an alignment image hereinafter, and an alignment mark position measured by the alignment measuring device 106 will be referred to as an alignment measurement value hereinafter. An example of the alignment image observed by the alignment measuring device 106 is an image obtained by capturing reflected light from each alignment mark of the substrate S and the mold M. Alternatively, the alignment image may be an image obtained by capturing an image formed by moiré of each alignment mark of the substrate S and the mold M. The curing unit 107 irradiates the imprint material with energy (for example, light such as UV light) for curing the imprint material IM via the optical member 111, thereby curing the imprint material. The image capturing unit 112 captures the substrate S, the mold M, and the imprint material IM via the optical member 111 and the window member 125. An image captured by the image capturing unit 112 will be referred to as a spread image hereinafter.

The imprint apparatus IMP can include a dispenser 108 that arranges a plurality of droplets of the imprint material IM on the substrate S. In the following description, the droplet indicates a droplet of the imprint material IM as a curable composition. The dispenser 108, for example, discharges the imprint material IM so that a plurality of droplets of the imprint material IM are arranged on the substrate S in accordance with droplet arrangement information representing the arrangement of the plurality of droplets of the imprint material IM. The imprint apparatus IMP can include a control unit 110 that controls the substrate driving mechanism 105, the mold driving mechanism 122, the deformation mechanism 123, the mold conveyance mechanism 140, the mold cleaner 150, the alignment measuring device 106, the curing unit 107, the image capturing unit 112, the dispenser 108, and the like. The control unit 110 can be formed by, for example, a PLD (the abbreviation of Programmable Logic Device) such as an FPGA (the abbreviation of Field Programmable Gate Array), an ASIC (the abbreviation of Application Specific Integrated Circuit), a general-purpose computer incorporating a program, or a combination of some or all of these, as denoted by reference numeral 113.

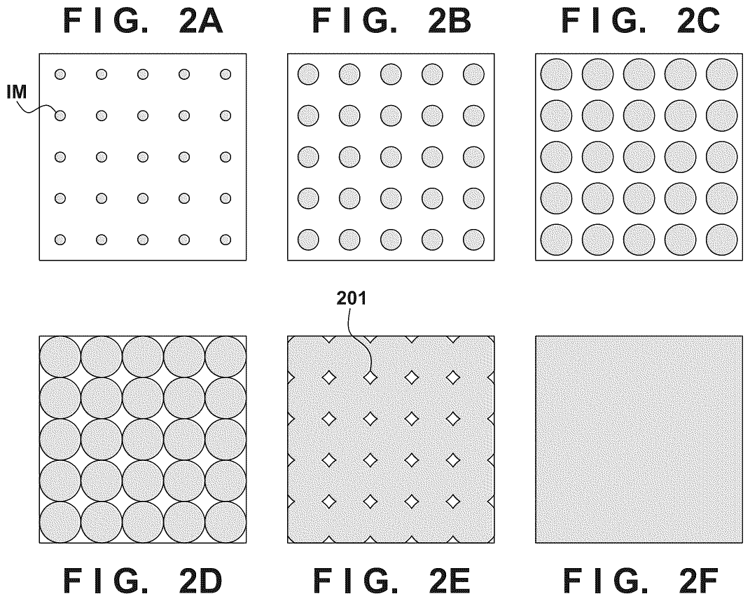

FIGS. 2A to 2F each show a state in which the plurality of droplets of the imprint material IM spread in a process of pressing the mold M against the plurality of droplets of the imprint material IM. FIG. 2A shows a state, immediately after the plurality of droplets of the imprint material IM are arranged on the substrate S, in which each droplet is small and the plurality of droplets are separated from each other. After that, by continuously pressing the mold M, the adjacent droplets spread to contact each other at the time of FIG. 2D. Finally, as shown in FIG. 2F, a film of the imprint material IM spreads over the entire mold M.

In a process in which the plurality of droplets spread, bubbles 201 can be formed among the plurality of droplets in a space between the mold M and the substrate S, as shown in FIG. 2E. If a liquid film of the imprint material IM is cured in the state in which the bubble 201 exists, the portion of the bubble 201 becomes a defect. Therefore, to improve the production performance of the imprint apparatus IMP, it is important to decrease the size of the bubble 201 and make the bubble 201 disappear in a short time.

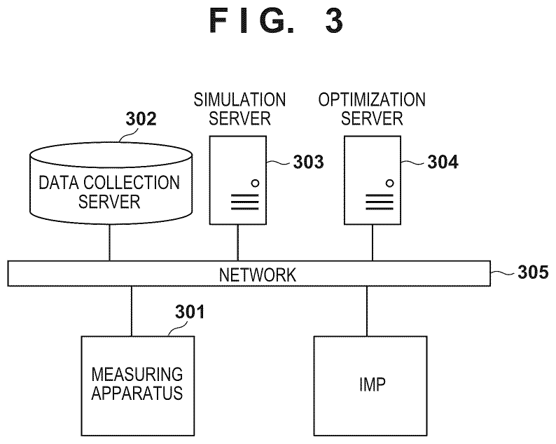

FIG. 3 exemplifies the arrangement of a system that generates droplet arrangement information (droplet arrangement pattern) representing the arrangement of a plurality of droplets of the imprint material IM. An optimization server (information processing apparatus) 304 can include a program for deciding the arrangement of a plurality of droplets or generating droplet arrangement information, and a processor (CPU) for executing the program. The optimization server 304 can perform machine learning. Data necessary to perform machine learning in the optimization server 304 can be collected from a data collection server 302 via a network 305. A measuring apparatus 301 is an apparatus that measures or inspects the state of the substrate S processed by the imprint apparatus IMP. A measurement result measured by the measuring apparatus 301 can be provided to the data collection server 302 via the network 305, and accumulated in the data collection server 302. A simulation server 303 includes a simulator that performs a physical simulation of the imprint process of the imprint apparatus IMP. The simulator can generate prediction result data similar to the measurement result data measured by the measuring apparatus 301 by simulating the imprint process. The prediction result data generated by the simulation server 303 can be provided to the data collection server 302 via the network 305, and accumulated in the data collection server 302.

The data collection server 302 accumulates the measurement result data. The data collection server 302 receives, via the network 305, the measurement result data from the measuring apparatus 301 and the prediction result data from the simulation server 303. Furthermore, the data collection server 302 transmits measurement data to the optimization server 304 via the network 305. The imprint apparatus IMP receives droplet arrangement information from the optimization server 304 via the network 305. The imprint apparatus IMP can operate to arrange a plurality of droplets on the substrate S in accordance with the received droplet arrangement information.

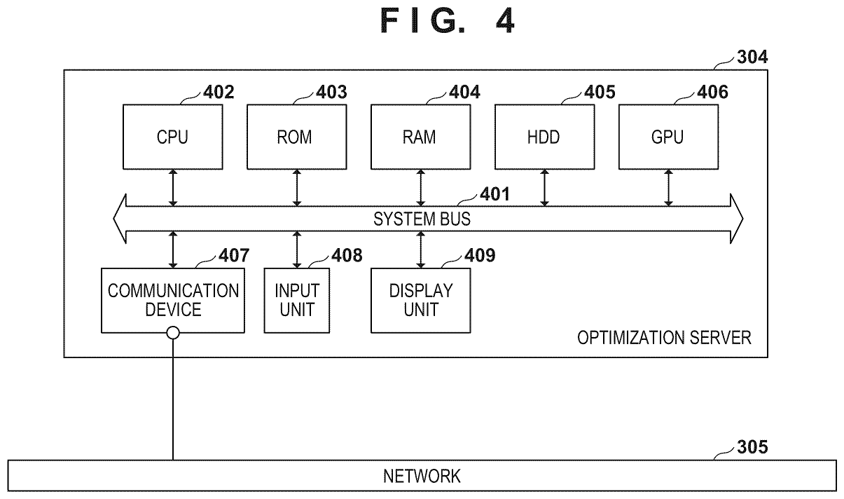

FIG. 4 exemplifies the hardware arrangement of the information processing apparatus formed by the optimization server 304. In the example of FIG. 4, a CPU 402 is a processor that performs calculation for control in accordance with a program, and controls each component connected to a system bus 401. A ROM 403 is a data read-only memory, and stores programs and data. A RAM 404 is a data read/write memory, and is used to save programs and data. The RAM 404 is also used to temporarily save data such as a result of calculation by the CPU 402. An HDD 405 is used as a temporary save area for the Operating System (OS) of the information processing apparatus, programs, and data. The HDD 405 is slower to input and output data than the RAM 404, but can save a large amount of data. The HDD 405 is desirably a nonvolatile storage device that can save data as permanent data so that the data can be referred to over a long period of time. In FIG. 4, a magnetic storage device (HDD) is formed as a storage device but a device that reads/writes data from/in an external medium such as a CD, a DVD, or a memory card loaded to the device may be formed. A GPU 406 is an arithmetic processing unit that can perform more parallel calculation processes than the CPU 402. Parts of an inference process and a learning process in machine learning are performed by the GPU 406 in accordance with the contents of the program. A communication device 407 is connected to the network 305 to perform data communication by a communication protocol such as TCP/IP, and is used when performing mutual communication with another information processing apparatus. An input device 408 is a device used to input characters and data to the information processing apparatus, and includes various kinds of keyboards and a mouse. A display device 409 is a device used to display information necessary for the operation of the information processing apparatus, a processing result, and the like, and includes a CRT or a liquid crystal monitor.

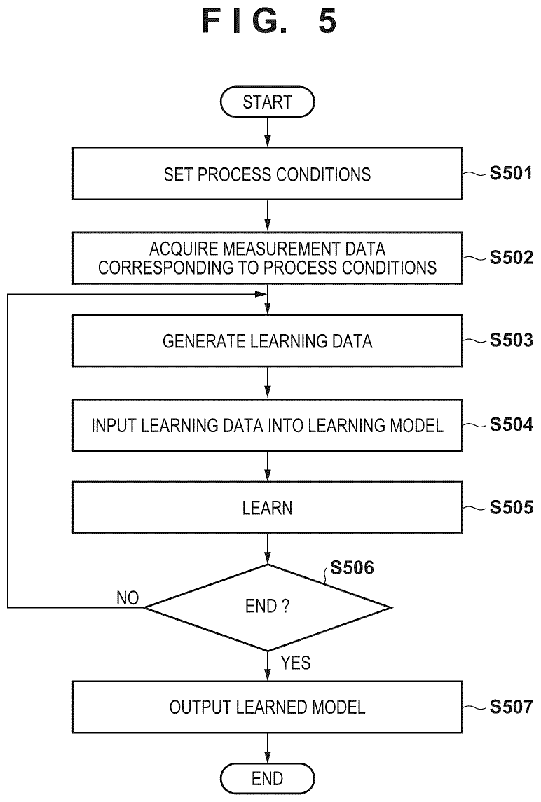

In this embodiment, a machine learning technique is used in a process of generating droplet arrangement information representing the arrangement of a plurality of droplets of the imprint material IM as a curable composition. FIG. 5 exemplifies an information processing method of generating a learned model using measurement data. The learned model is generated by the optimization server 304. The learned model is a learning model obtained after learning, and is preferably a learning model for which it is determined that learning is ended.

In step S501, process conditions are set. The process conditions can include imprint conditions and droplet arrangement information. The imprint conditions can include, for example, the specifications of the mold M, the target value of the thickness of a film of the imprint material IM to be formed, the depth of a groove in the pattern region MP of the mold M, and pattern information of the pattern region MP.

In step S502, the optimization server 304 requests the data collection server 302 to provide measurement data corresponding the process conditions set in step S501. At this time, a request is transmitted from the optimization server 304 to the data collection server 302 via the network 305. Upon receiving the request, the data collection server 302 extracts the requested measurement data corresponding to the process conditions from a measurement data database held by the data collection server 302. The data collection server 302 transmits the extracted measurement data to the optimization server 304 via the network 305.

In this way, the optimization server 304 acquires the measurement data corresponding to the process conditions set in step S501 from the data collection server 302.

In step S503, the optimization server 304 generates learning data including measurement data as supervised data and training data corresponding to it using the measurement data received from the data collection server 302.

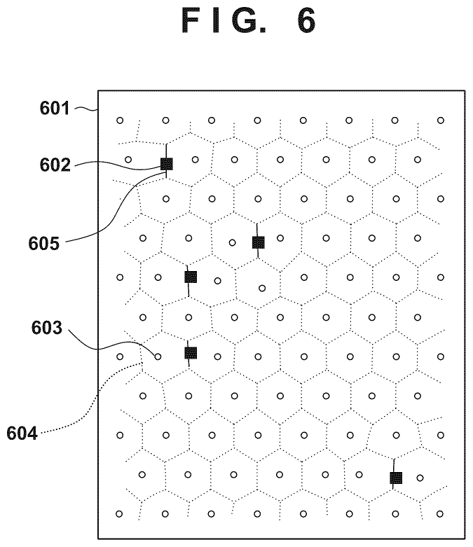

FIG. 6 exemplifies the supervised data generated in step S503. The measurement data as the supervised data can include information representing the position and size of a defect 602 included in a shot region 601 of the substrate S. The optimization server 304 can create a Voronoi diagram in which a position 603 of each droplet of the imprint material IM is set as a generating point. The Voronoi diagram is a diagram obtained by partitioning a plane based on a specific generating point to which an arbitrary point on the plane is closest. Reference numeral 604 denotes boundary lines of the partitioned regions. A bubble generated as the defect 602 in the film of the imprint material IM can appear on the boundary line 604 far from the position 603 of the closest droplet. Next, the optimization server 304 can associate the defect 602 with the boundary line 604. For example, the optimization server 304 can search for the boundary line 604 closest to the defect 602 in FIG. 6, thereby associating the defect with the boundary line 604 to indicate that the defect 602 is a defect generated near a boundary line 605. Information concerning the presence/absence of generation of the defect 602 with respect to each boundary line 604 and the size of the defect serves as supervised data. The process conditions serve as training data.

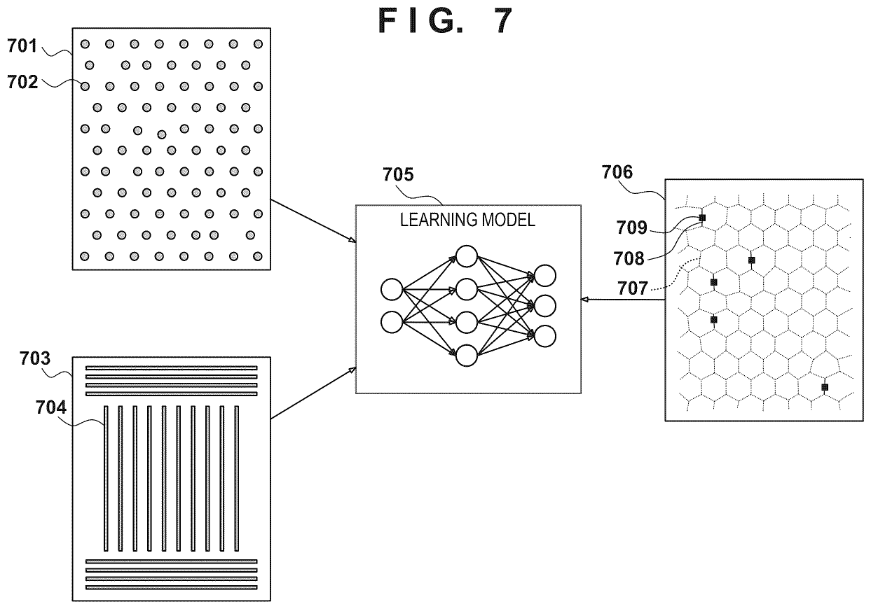

In step S504, the optimization server 304 inputs learning data (training data and supervised data) generated in step S503 to a learning model. FIG. 7 schematically shows an overview of providing, to a learning model, learning data including training data and supervised data, to perform learning, and generating a learned model. The training data includes droplet arrangement information 701 representing the arrangement of droplets of the imprint material IM. The droplet arrangement information 701 can include, for example, information representing positions (coordinates) at which a plurality of droplets 702 of the imprint material IM are arranged and the volume of each droplet 702. The training data can further include pattern information 703 of the mold M as one of the process conditions (imprint conditions). The pattern information 703 can include information representing a pattern 704 of the mold M (a pattern to be transferred to the substrate S). Supervised data 706 can include defect information as information concerning the presence/absence of generation of a defect with respect to each boundary line in a Voronoi diagram and the size of the defect. In this example, a boundary line 707 represented by a broken line indicates a state in which there is no defect. A boundary line 708 represented by a solid line indicates a state in which there is a defect 709, and is associated with information concerning the position and size of the defect 709.

In step S505, the optimization server 304 causes the learning model to perform learning using the above-described learning data (training data and supervised data), thereby generating a learned model. Generation of the learned model includes decision of a parameter value of a learning model 705. Information of the learning model 705 includes information representing the structure of a neural network such as the number of layers of a perceptron and the number of neurons, and a random variable included in the learning model can be optimized by learning. For the learning model, it is also possible to use a data structure in which nodes are connected by links each representing an adjacency relationship, like a graph neural network.

In step S506, the optimization server 304 confirms whether the learning data corresponding to all the measurement data acquired in step S502 have been used for learning. If there exists learning data that has not been used for learning, the processes in steps S503 to S505 are repeatedly performed. In step S507, the optimization server 304 outputs the learning model 705 after learning is ended, that is, the learned model.

When causing the learning model to perform learning, it may be desirable to perform learning using conditions in which the imprint apparatus IMP performs no imprint process. In this case, it is effective to perform calculation with respect to the conditions by a simulator simulating the imprint process, generate learning data for learning using the calculation result of the simulator, and perform learning using the learning data.

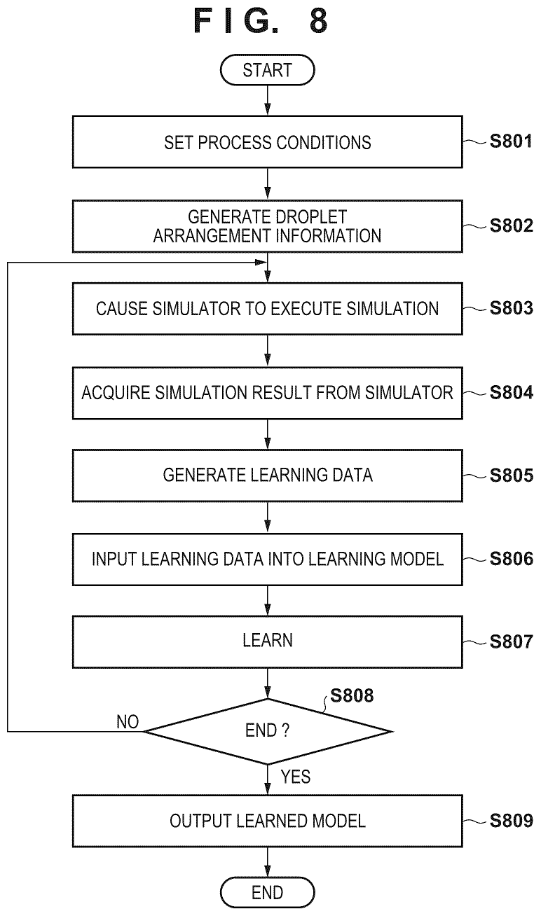

FIG. 8 exemplifies a method of generating a learned model using a simulation result generated using a simulator. The learned model is generated by the optimization server 304. In step S801, process conditions are set. The process conditions include imprint conditions and droplet arrangement information. The imprint conditions can include, for example, the specifications of the mold M, the target value of the thickness of a film of the imprint material IM to be formed, the depth of a groove in the pattern region MP of the mold M, and pattern information of the pattern region MP.

In step S802, the optimization server 304 generates a plurality of different pieces of droplet arrangement information. The plurality of different pieces of droplet arrangement information can be generated by, for example, moving the positions of a plurality of droplets in the droplet arrangement information set in step S801 in accordance with random values. In step S803, the optimization server 304 selects one piece of droplet arrangement information from the plurality of pieces of droplet arrangement information generated in step S802, and requests the simulation server 303 (simulator) to execute a simulation using the selected droplet arrangement information as a simulation condition. The simulation server 303 executes a simulation in accordance with the requested simulation condition, and provides prediction data as a simulation result to the optimization server 304.

In step S804, the optimization server 304 receives the prediction data provided from the simulation server 303. In step S805, the optimization server 304 generates learning data including prediction data as supervised data and training data corresponding to it using the received prediction data.

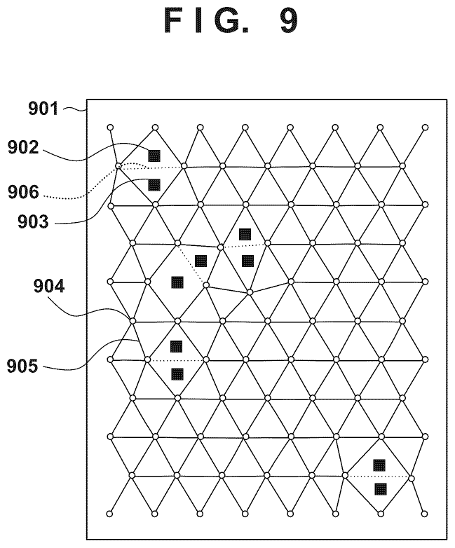

FIG. 9 exemplifies the supervised data generated in step S805. The prediction data as the supervised data can include information representing the positions and sizes of defects 902 and 903 included in a shot region 901 of the substrate S. The optimization server 304 can acquire positions 904 of a plurality of droplets of the imprint material IM, thereby generating a Delaunay diagram in which adjacent droplets are connected by a link. Next, the optimization server 304 associates the link with the defect. In FIG. 9, the defects 902 and 903 exist on both sides of a link 906. These defects can be considered as defects generated when two droplets on both sides of the link 906 are not merged. Thus, the optimization server 304 adds information representing that the two droplets on both sides of the link 906 are not merged. In the example shown in FIG. 9, a link for droplets on its both sides that are not merged is indicated by a broken line. On the other hand, with respect to a link, such as a link 905, for which no defects are generated on both sides, the optimization server 304 adds information representing that two droplets on both sides of the link are merged. In the example shown in FIG. 9, a link for two droplets at its both ends that are merged is indicated by a solid line. The information that represents whether droplets at both ends of a link are merged and is added to the link serves as supervised data. If a time during which the mold M is pressed against the imprint material IM is long, adjacent droplets are readily merged. The length of the time during which the droplet and the mold M are in contact with each other is different between a portion near the center of the shot region where the droplet contacts the mold M at an early timing and a portion on the periphery of the shot region where the droplet contacts the mold M at a late timing. Therefore, as information of the presence/absence of merging of droplets, prediction data obtained by a simulation at a timing close to a timing when the droplet contacts the mold M may be used.

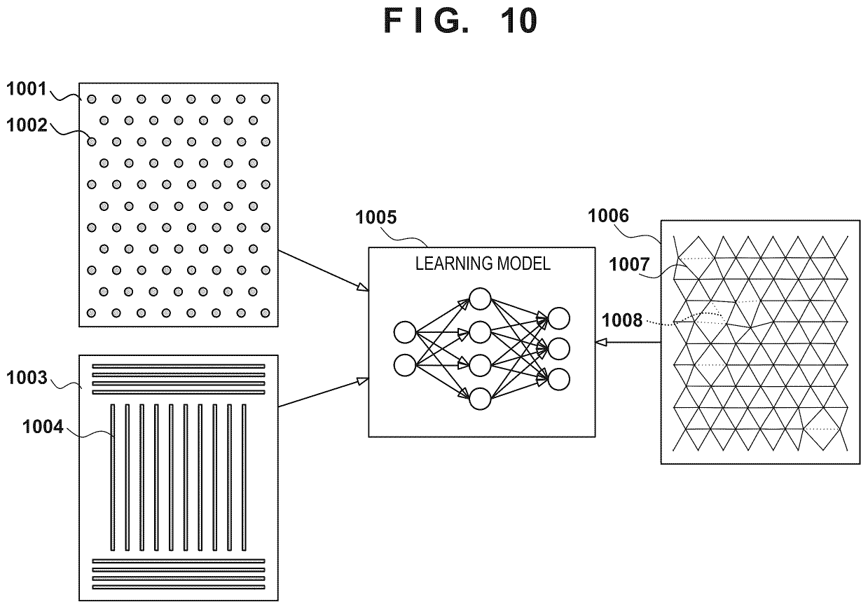

In step S806, the optimization server 304 inputs the learning data (training data and supervised data) generated in step S805 to the learning model. FIG. 10 schematically shows an overview of providing, to a learning model, learning data including training data and supervised data, to perform learning, and generating a learned model. The training data includes droplet arrangement information 1001 representing the arrangement of droplets of the imprint material IM. The droplet arrangement information 1001 can include information representing positions (coordinates) at which a plurality of droplets of the imprint material IM are arranged and the volume of each droplet. The training data can further include pattern information 1003 of the mold M as one of the process conditions (imprint conditions). The pattern information 1003 can include information representing a pattern 1004 of the mold M (a pattern to be transferred to the substrate S). In supervised data 1006, a link connecting adjacent droplets is added with merging information between droplets at both ends of the link. A link 1008 indicated by a broken line includes a state in which droplets at both ends are not merged, and a link 1007 indicated by a solid line includes a state in which droplets at both ends are merged.

In step S807, the optimization server 304 causes the learning model to perform learning using the above-described learning data (training data and supervised data), thereby generating a learned model. The learned model includes decision of a parameter value of a learning model 1005. Information of the learning model 1005 includes information representing the structure of a neural network such as the number of layers of a perceptron and the number of neurons, and a random variable included in the learning model can be optimized by learning. For the learning model, it is also possible to use a data structure in which nodes are connected by links each representing an adjacency relationship, like a graph neural network. Information output from the learned model can include a merging probability pᵢⱼ representing the ease of merging of droplets at both ends of the link. For example, referring to FIG. 10, a value close to 1 is output as the merging probability on the link 1007 where the droplets at both ends of the link are merged. On the other hand, a value close to 0 is output as the merging probability on the link 1008 where the droplets at both ends of the link are not merged. The merging probability pᵢⱼ can be understood as the evaluation value of the plurality of droplets according to the droplet arrangement information, and more specifically, an index indicating the state of a liquid film formed by the plurality of droplets according to the droplet arrangement information.

In step S808, the optimization server 304 confirms whether all the pieces of droplet arrangement information generated in step S802 have been used for learning. If there exists droplet arrangement information that has not been used for learning, the processes in steps S803 to S807 are repeatedly performed. In step S809, the optimization server 304 outputs the learning model 1005 after learning is ended, that is, the learned model.

The thus generated learned model can output information of the presence/absence of a defect and merging prediction of the droplets on both ends of the link. By using the learned model, it is possible to predict a complicated behavior that is the interaction between droplets, instead of a physical simulation.

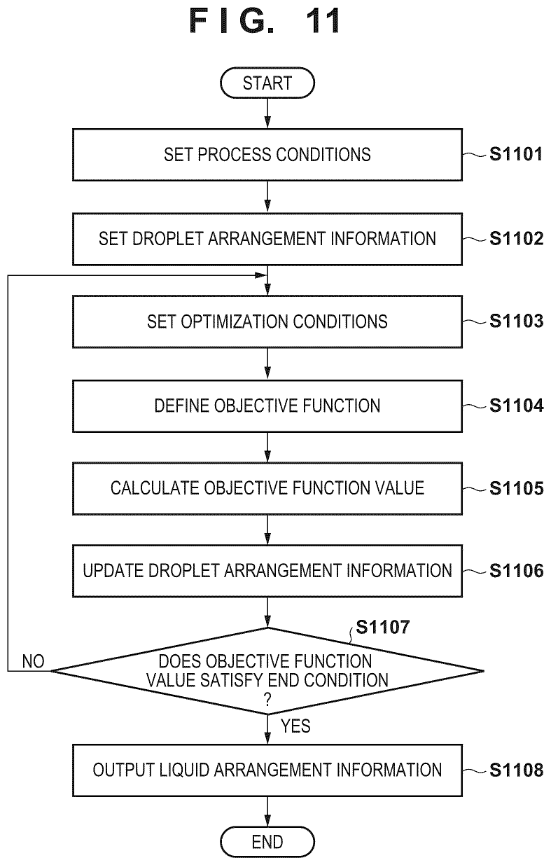

Next, a generation method or an information processing method of generating droplet arrangement information representing the arrangement of a plurality of droplets of the imprint material IM as a curable composition using the generated learned model will be described. FIG. 11 shows the procedure of the generation method or the information processing method of generating droplet arrangement information. The method shown in FIG. 11 can be executed by the optimization server 304.

In step S1101, process conditions are set. The process conditions include imprint conditions. The imprint conditions can include, for example, the specifications of the mold M, the target value of the thickness of a film of the imprint material IM to be formed, the depth of a groove in the pattern region MP of the mold M, and pattern information of the pattern region MP. In step S1102, droplet arrangement information to be optimized can be set. The set droplet arrangement information may be default droplet arrangement information, or may automatically be generated in accordance with a predetermined algorithm based on the process conditions set in step S1101.

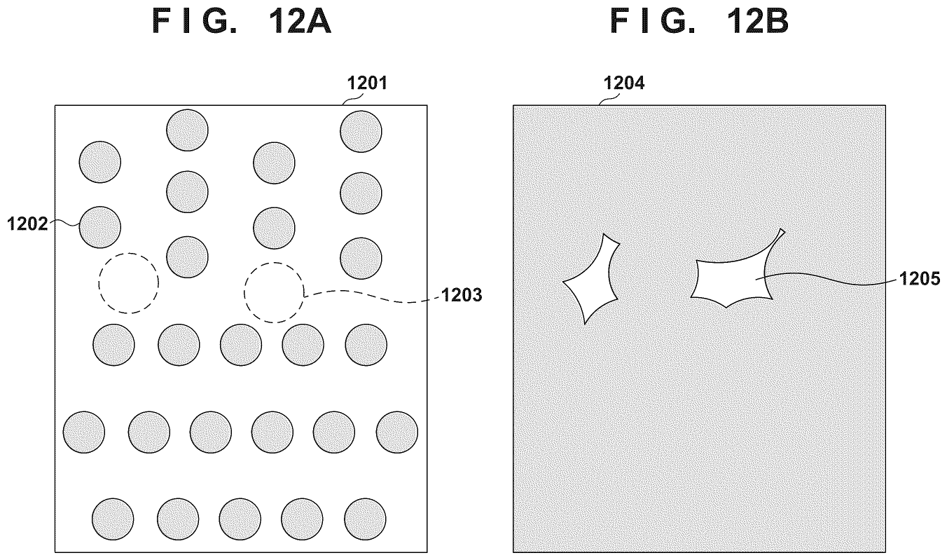

FIG. 12A exemplifies droplet arrangement information (droplet arrangement pattern) to be optimized. FIG. 12A exemplifies the arrangement of a plurality of droplets 1202 in a shot region 1201 of the substrate S. In the shot region 1201, a region 1203 is a region where the droplets are coarsely arranged. FIG. 12B exemplifies a film of the imprint material formed by pressing the mold M against the plurality of droplets in the arrangement of the plurality of droplets shown in FIG. 12A. In FIG. 12B, bubbles 1205 are generated in the film in a region after pressing the mold M, which corresponds to the region 1203 where the droplets are roughly arranged. In a process to be described below, by performing optimization calculation for the droplet arrangement information set in step S1102, droplet arrangement information that can decrease the generation of the bubbles 1205 or the area of each bubble 1205 is generated.

In step S1103, optimization conditions are set. Setting of the optimization conditions can include, for example, setting of a learned model, setting of hyperparameters of machine learning, and setting of an algorithm used for optimization calculation. In step S1104, the optimization server 304 defines an objective function L based on the process conditions set in step S1101, the droplet arrangement information set in step S1102, and the optimization conditions set in step S1103.

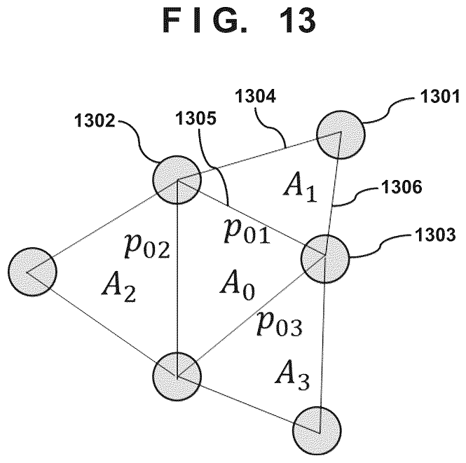

The objective function L will exemplarily be described with reference to FIG. 13. Referring to FIG. 13, reference numerals 1301, 1302, and 1303 denote droplets; and 1304, 1305, and 1306, links each connecting droplets. Reference symbols A₁, A₂, and A₃ denote cell regions each surrounded by the links. The cell region A₁ is a region surrounded by the link 1304 connecting the droplets 1301 and 1302, the link 1305 connecting the droplets 1302 and 1303, and the link 1306 connecting the droplets 1303 and 1301. Reference symbols p₀₁, p₀₂, and p₀₃ each denote a merging probability between droplets at both ends of a link. Each of the merging probabilities p₀₁, p₀₂, and p₀₃ has a value close to 1 in a case where the droplets are readily merged and has a value close to 0 in a case where the droplets are hardly merged. For example, p₀₁ represents the merging probability between the droplets 1302 and 1303 at both ends of the link 1305. Each of the cell regions A₁, A₂, and A₃ is a region where there exists a bubble.

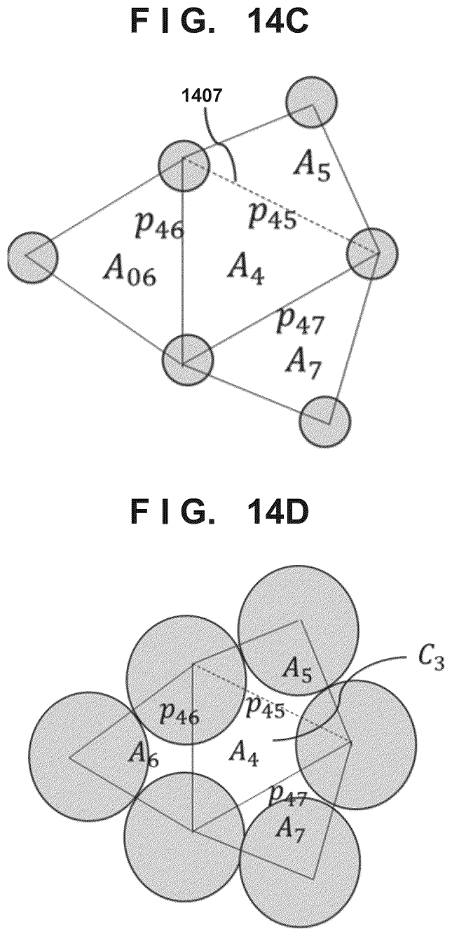

FIG. 15 schematically shows a method of estimating the value of the merging probability pᵢⱼ included in the variables of the objective function L using a learned model. Droplet arrangement information 1501 defines the arrangement of a plurality of droplets 1502 in a shot region of the substrate S. Pattern information 1503 is information that is set in step S1101 and defines a pattern 1504 of the mold M. A learned model 1505 outputs estimation data 1506 including the merging probability pᵢⱼ in response to the input of the droplet arrangement information 1501 and the pattern information 1503. As shown in FIG. 15, as a result of the estimation, the merging probability p₀₁ has a value close to 0 in a case where the droplets at both ends of the link are hardly merged on a link at the boundary between the cell regions A₀ and A₁. On the other hand, as a result of the estimation, the merging probability p₀₂ has a value close to 1 in a case where the droplets at both ends of the link are readily merged on a link at the boundary between the cell regions A₀ and A₂. The value of the objective function L given by equation (3) is calculated by substituting the merging probability pᵢⱼ estimated by the learned model into equation (1) or (2).

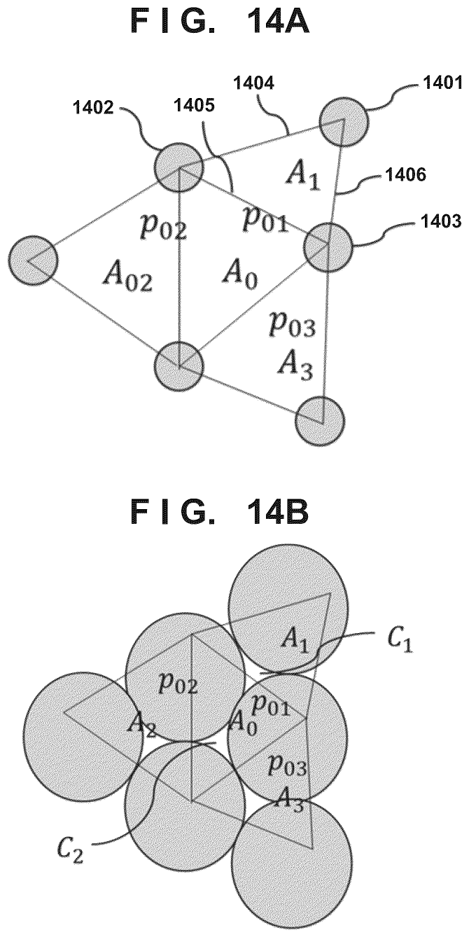

FIGS. 14A to 14D exemplify the value of the objective function L corresponding to each of different pieces of droplet arrangement information. FIG. 14B shows a state in which a plurality of droplets spread when pressing the mold M with respect to the droplet arrangement information (droplet arrangement pattern) shown in FIG. 14A. In FIG. 14B, bubbles C₁ and C₂ are generated. On the other hand, FIG. 14D shows a state in which a plurality of droplets spread when pressing the mold M with respect to the droplet arrangement information (droplet arrangement pattern) shown in FIG. 14C. In FIG. 14C, droplets at both ends of a link 1407 are not merged, and a cluster C₃ as a set of bubble regions across cell regions A₄ and A₅ is formed.

When considering up to a cell region Aⱼ adjacent to a cell region Aᵢ, a cluster Cᵢ having a bubble size is given by:

$${C}_{i} = area ( {A}_{i} ) + {\sum }_{j ∈ {N}_{i}} ( 1 - {p}_{ij} ) area ( {A}_{j} ) \qquad ( 1 )$$

In equation (1), Nᵢ represents a set of cell indices adjacent to the cell region Aᵢ, and area(Aᵢ) represents a value corresponding to the area of the cell region Aⱼ or an amount of bubbles that can be generated in the cell region Aᵢ. Furthermore, the cluster Cᵢ can be formed across a plurality of cell regions Aᵢ including the cell region Aᵢ that is not adjacent.

When also considering two cell regions adjacent to the cell region Aᵢ, the cluster Cᵢ having a bubble size is given by:

$${C}_{i} = area ( {A}_{i} ) + {\sum }_{j ∈ {N}_{i}} ( 1 - {p}_{ij} ) [ area ( {A}_{j} ) + {\sum }_{k ∈ {N}_{j} \backslash i} ( 1 - {p}_{jk} ) area ( {A}_{k} ) ] \qquad ( 2 )$$

In equation (2), Nᵢ represents a set of cell indices adjacent to the cell region Aᵢ, and N_{j\i} represents a set obtained by excluding an index i from the set of the indices adjacent to the cell region Aᵢ. Furthermore, in equation (2), area(Aᵢ) represents a value corresponding to the area of the cell region Aᵢ or an amount of bubbles that can be generated in the cell region Aᵢ.

To prevent bubbles from remaining in a film formed by a plurality of droplets of the imprint material IM in pressing the mold M against the plurality of droplets, it is necessary decrease the amount of bubbles formed in the film. Therefore, the objective function L can be defined to decrease the total amount of the cluster Cᵢ as a set of bubble regions.

$$L = {\sum }_{i} {\vert {C}_{i} \vert}^{n} \qquad ( 3 )$$

In equation (3), n represents an arbitrary number of 1 or more. As n increases, the effect of intensively decreasing the cluster cell whose expected area value is large is obtained.

In step S1105, the optimization server 304 calculates the value of the objective function L defined in step S1104 based on the merging probability given by the learned model.

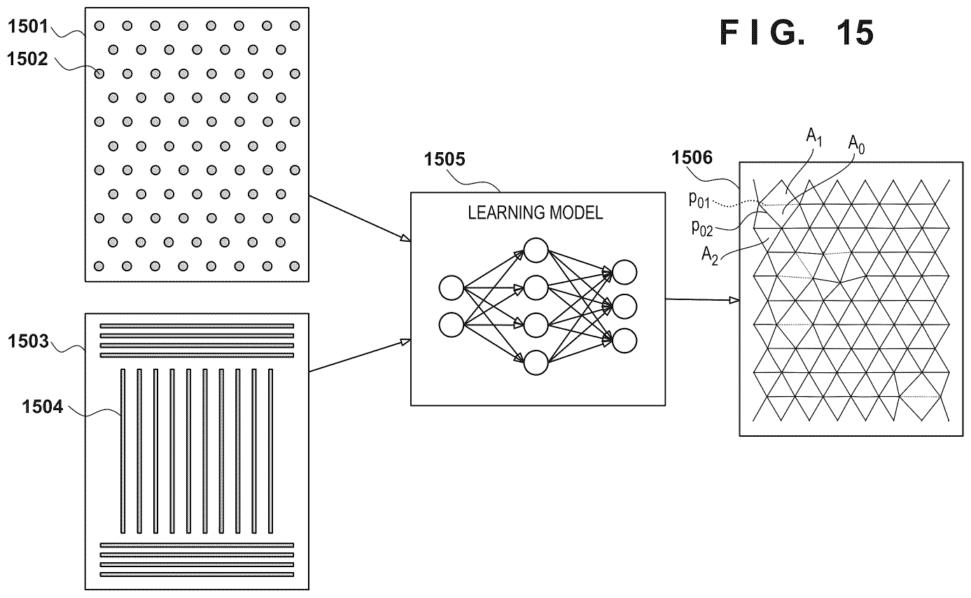

In step S1106, the optimization server 304 updates the droplet arrangement information (droplet arrangement pattern). FIG. 16 schematically shows a process of updating the droplet arrangement information, that is, the arrangement pattern of a plurality of droplets. Reference numeral 1601 denotes a position of a droplet before update; 1602, a movement vector applied to a corresponding droplet; and 1603, a position of a droplet after update. By moving the position of the position 1601 before update in accordance with the movement vector 1602, the position of the position 1603 after update is decided.

In the process of updating the droplet arrangement information, the arrangement of the plurality of moved droplets can be decided so as to decrease the value of the objective function L through optimization calculation. As an optimization calculation method of deciding the arrangement of a plurality of droplets, there is provided, for example, gradient descent. In gradient descent, the moving direction of each droplet is decided by obtaining a value differentiated by the coordinates of the droplet of the value of objective function. After that, with respect to the above moving method, a small coefficient is multiplied to decide the movement vector 1602. In the process shown in FIG. 11, movement of the droplet by such movement vector group that the value of the objective function L decreases is repeated, and in the repetitive process, the arrangement pattern of the droplets with which the value of the objective function Lis smallest can be a result of optimization calculation.

In step S1107, the optimization server 304 evaluates the droplet arrangement information obtained in step S1106. In this example, it is determined whether the value of the objective function L satisfies an end condition, for example, whether the value of the objective function L reaches the target value. As a more practical example, if the value of the objective function L is smaller than the target value of the bubble size in a target filling time, it can be determined that the value reaches the target value. In this specification, optimization includes not only optimization, in a narrow sense, of obtaining an optimum solution but also, for example, optimization, in a broad sense, of aborting the process when the end condition is satisfied.

If it is determined in step S1107 that the droplet arrangement information does not reach the target value, the optimization server 304 repeats steps S1103 to S1106. In step S1108, the optimization server 304 outputs the droplet arrangement information that satisfies the end condition when the value of the objective function L reaches the target value. For example, the optimization server 304 transfers the droplet arrangement information to the imprint apparatus IMP via the network 305. The imprint apparatus IMP can execute an imprint process including a process of arranging a plurality of droplets on the substrate S in accordance with the droplet arrangement information received from the optimization server 304. The optimization server 304 can be understood as an information processing apparatus including an updater configured to update the arrangement of a plurality of droplets until an evaluation result of the arrangement satisfies the end condition while performing evaluation using a learned model that receives the arrangement and outputs an evaluation value of the arrangement.

In the process example shown in FIG. 11, the droplet arrangement information is generated using the learning model generated based on the prediction data obtained by the simulator. On the other hand, in optimization calculation, the droplet arrangement information may be generated using the learning model generated using the measurement data, as shown in FIG. 7.

In equation (4) below, calculation of the cluster Cᵢ when the measurement data is used is exemplified.

$${C}_{i} = {D}_{i} + {\sum }_{j ∈ ( neighbors - i )} {D}_{j} \qquad ( 4 )$$

In equation (4), Di represents measurement data indicating the size of the defect 602 exemplified in FIG. 6. Cᵢ represents the sum of defects generated around droplets. By using equation (4) instead of equation (1), it is possible to perform optimization calculation using the learning model obtained based on the measurement data.

The objective function L given by equation (3) represents a combination of a plurality of droplets that decreases a bubble size evaluated by the value of Cᵢ. However, if the bubble size is decreased, the plurality of droplets are dense, and thus such droplet arrangement information that the bubble size is small but a thickness different from the target thickness of a film of the curable composition is obtained may be generated. Therefore, optimization may be performed so as to decrease the bubble size and make the film thickness of the curable composition close to the target.

The objective function L that decreases the bubble size and considers the difference between the calculated film thickness and the target film thickness in optimization calculation will be exemplified below.

$$L = {\sum }_{i} {( {C}_{i} )}^{2} + k * {\sum }_{i} {( {R}_{i} - {R}_{target} )}^{2} \qquad ( 5 )$$

where k represents a constant for adjusting a ratio indicating which of the bubble size and the film thickness (uniformization thereof) is prioritized in optimization. Rᵢ represents the film thickness of each droplet and R_{target} represents the target film thickness.

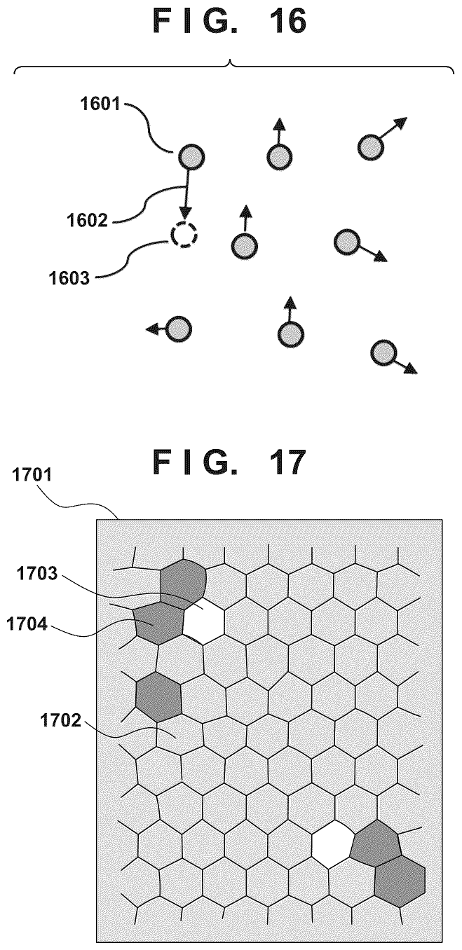

FIG. 17 schematically shows the difference in film thickness between droplets. Referring to FIG. 17, in a Voronoi diagram of a shot region 1701, the film thickness of each droplet is represented by a color for each Voronoi region to which each droplet belongs. A droplet 1702 has a film thickness equal to the target film thickness R_{target}. A droplet 1703 has a film thickness smaller than the target film thickness R_{target}. A droplet 1704 has a film thickness larger than the target film thickness R_{target}. In addition to a term for decreasing the bubble size, equation (5) includes a term given by:

$${\sum }_{i} {( {R}_{i} - {R}_{target} )}^{2} \qquad ( 6 )$$

If the objective function includes only a term for decreasing the bubble size, as given by equation (3), the droplets may be arranged to be dense in order to decrease the bubble size. In this case, the purpose of decreasing the bubble size is achieved, but the droplets may be arranged to have film thicknesses different from the desired one. Therefore, in equation (5), the objective function L is defined to evaluate both the bubble size and the film thickness. Furthermore, the objective function L may be defined to include only the term of the film thickness.

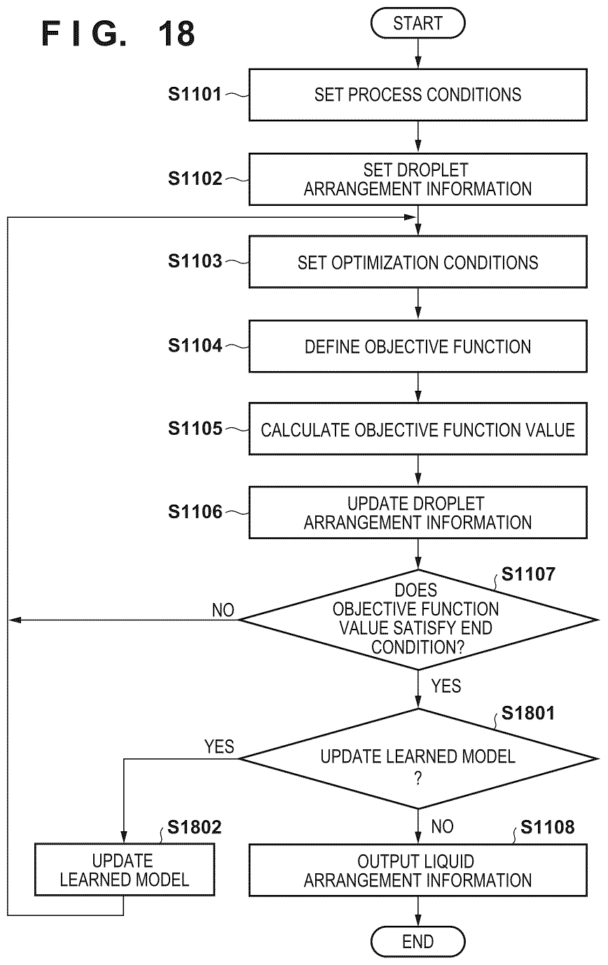

In the method shown in FIG. 11, the learned model is set in step S1103. As optimization progresses in the method shown in FIG. 11, the difference between the droplet arrangement information used to generate the learned model and the droplet arrangement information updated in step S1106 may become large. A case where the difference becomes large can include a case where prediction using the learned model is not performed correctly in step S1105. FIG. 18 shows a modification of the method shown in FIG. 11. In the method shown in FIG. 18, steps S1801 and S1802 are added to the method shown in FIG. 11. In step S1801, it is determined whether to update the learned model. This determination process can include, for example, determination of whether the number of times the droplet arrangement information is updated is equal to or larger than a predetermined number. Alternatively, this determination process can include determination of whether the difference between the droplet arrangement information used to generate the learned model and the droplet arrangement information updated in step S1106 is equal to or larger than a predetermined amount. If it is determined, in step S1801, to update the learned model, the learned model is updated in step S1802, and then steps S1103 to S1107 are repeated.

In this embodiment, in consideration of merging of the adjacent droplets, it is possible to generate droplet arrangement information that can decrease the size of a bubble surrounded by the adjacent droplets. In this method, information obtained by the interaction between adjacent droplets, that is, the merging probability is calculated using the learned model instead of the simulator. In general, optimization calculation requires many repetitive processes. If physical calculation like the simulator is performed in the loop of optimization calculation, a large calculation resource is required. However, by the method according to this embodiment, it is possible to suppress the calculation resource using the learned model instead of calculation of the simulator.

In the above embodiment, using a learned model that receives an arrangement of a plurality of droplets of a curable composition and outputs the state of a liquid film formed by connecting the plurality of droplets, the value of an objective function is calculated based on the state of the liquid film. However, as the learned model, a learned model that receives an arrangement of a plurality of droplets of a curable composition and outputs an evaluation value of the arrangement of the plurality of droplets may be used. In this case, an information processing method can include an update step of updating an arrangement of a plurality of droplets until an evaluation result of the arrangement of the plurality of droplets satisfies an end condition while evaluating the arrangement of the plurality of droplets using a learned model that receives the arrangement of the plurality of droplets and outputs an evaluation value of the arrangement of the plurality of droplets.

In the above embodiment, a liquid film is formed from a plurality of droplets of a curable composition by arranging the plurality of droplets on a substrate, bringing a mold into contact with the plurality of droplets, and the liquid film is cured to form a cured film. However, the present invention is also applicable to an apparatus and method for forming a film without using a mold. In such apparatus and method, after a plurality of droplets of a curable composition are arranged on a substrate, each of the plurality of droplets spreads, thereby forming a liquid film.

A film forming method according to an embodiment of the present disclosure forms a cured film of a curable composition on a substrate. The film forming method can include a decision step of deciding an arrangement of a plurality of droplets of the curable composition in accordance with the above-described information processing method. The film forming method can further include a step of forming the cured film by arranging the plurality of droplets on a substrate in accordance with the arrangement decided in the decision step, and curing a liquid film formed by connecting the plurality of droplets.

An article manufacturing method according to an embodiment of the present disclosure can include a decision step of deciding an arrangement of a plurality of droplets of a curable composition in accordance with the above-described information processing method. The article manufacturing method can further include a step of forming a cured film by arranging the plurality of droplets on a substrate in accordance with the arrangement decided in the decision step, and curing a liquid film formed by connecting the plurality of droplets. The article manufacturing method can further include a processing step of obtaining the article by processing the substrate on which the cured film has been formed.

The pattern of a cured product formed using the imprint apparatus is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, an SRAM, a flash memory, and an MRAM and semiconductor elements such as an LSI, a CCD, an image sensor, and an FPGA. Examples of the mold are molds for imprint.

The pattern of the cured product is directly used as the constituent member of at least some of the above-described articles or used temporarily as a resist mask. After etching or ion implantation is performed in the substrate processing step, the resist mask is removed.

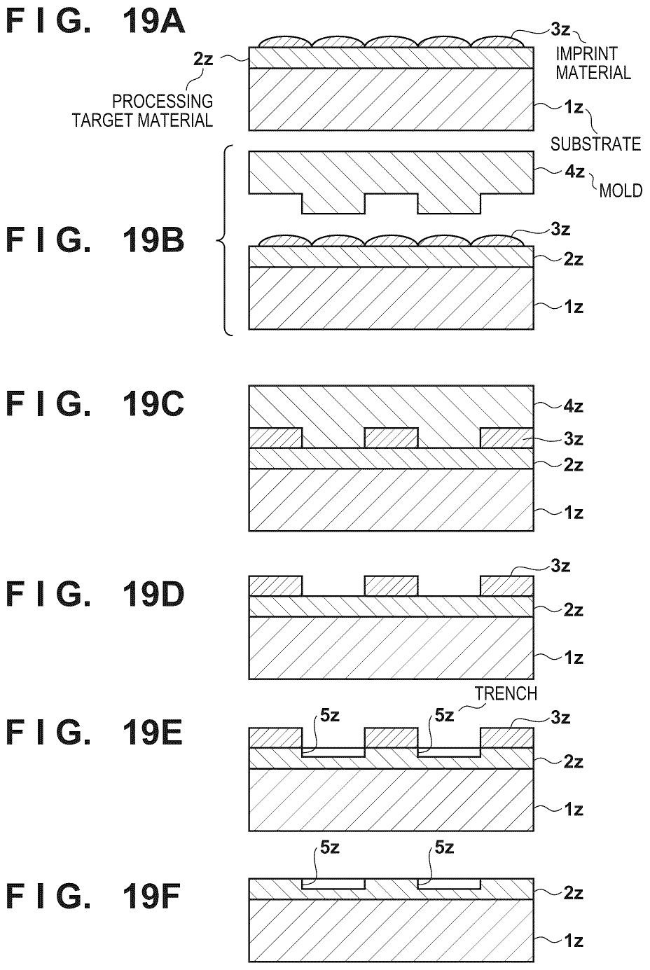

An article manufacturing method of forming a pattern on a substrate by an imprint apparatus, processing the substrate on which the pattern has been formed, and manufacturing an article from the substrate having undergone the process will be described next. As shown FIG. 19A, a substrate 1z such as a silicon wafer with a processed material 2z such as an insulator formed on the surface is prepared. Next, an imprint material 3z is applied to the surface of the processed material 2z by an inkjet method or the like. A state in which the imprint material 3z is applied as a plurality of droplets onto the substrate is shown here.

As shown in FIG. 19B, a side of a mold 4z for imprint with a pattern having concave and convex portions is directed to face the imprint material 3z on the substrate. As shown FIG. 19C, the mold 4z and the substrate 1z to which the imprint material 3z has been applied are brought into contact with each other, and a pressure is applied. The gap between the mold 4z and the processed material 2z is filled with the imprint material 3z. In this state, when the imprint material 3z is irradiated with light as curing energy via the mold 4z, the imprint material 3z is cured.

As shown in FIG. 19D, after the imprint material 3z is cured, the mold 4z is separated from the substrate 1z, and the pattern of the cured product of the imprint material 3z is formed on the substrate 1z. In the pattern of the cured product, the concave portion of the mold corresponds to the convex portion of the cured product, and the convex portion of the mold corresponds to the concave portion of the cured product. That is, the pattern having concave and convex portions of the mold 4z is transferred to the imprint material 3z.

As shown in FIG. 19E, when etching is performed using the pattern of the cured product as an etching resistant mask, a portion of the surface of the processed material 2z where the cured product does not exist or remains thin is removed to form a groove 5z. As shown in FIG. 19F, when the pattern of the cured product is removed, an article with the grooves 5z formed in the surface of the processed material 2z can be obtained. Here, the pattern of the cured product is removed. However, instead of removing the pattern of the cured product after the process, it may be used as, for example, an interlayer dielectric film included in a semiconductor element or the like, that is, a constituent member of an article.

### OTHER EMBODIMENTS

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-017825, filed Feb. 8, 2023, which is hereby incorporated by reference herein in its entirety.

What is claimed is:

1. An information processing method, applied to a film forming method of forming a cured film by arranging a plurality of droplets of a curable composition on a substrate and curing a liquid film formed by connecting the plurality of droplets, of deciding an arrangement of the plurality of droplets in the film forming method, comprising:
updating the arrangement of the plurality of droplets until an evaluation result of the arrangement of the plurality of droplets satisfies an end condition while evaluating the arrangement of the plurality of droplets using a learned model that receives the arrangement of the plurality of droplets and outputs an evaluation value of the arrangement of the plurality of droplets.

2. The method according to claim 1, further comprising generating the learned model by machine learning.

3. The method according to claim 2, wherein the evaluation value output by the learned model includes an index indicating a state of the liquid film.

4. The method according to claim 3, wherein in the updating, the arrangement of the plurality of droplets is changed until a value of an objective function for evaluating the arrangement of the plurality of droplets satisfies the end condition while calculating the value of the objective function using the index obtained using the learned model.

5. The method according to claim 4, wherein the index includes a merging probability between adjacent droplets among the plurality of droplets.

6. The method according to claim 5, wherein the objective function includes a term for evaluating a size of a bubble surrounded by adjacent droplets among the plurality of droplets.

7. The method according to claim 6, wherein the objective function includes a term for evaluating a thickness of the liquid film.

8. The method according to claim 1, wherein the updating includes deciding a direction in which a droplet is moved to update the arrangement of the plurality of droplets.

9. A non-transitory computer readable medium storing a program for causing a computer to execute processing, applied to a film forming method of forming a cured film by arranging a plurality of droplets of a curable composition on a substrate and curing a liquid film formed by connecting the plurality of droplets, of deciding an arrangement of the plurality of droplets in the film forming method, comprising:
updating the arrangement of the plurality of droplets until an evaluation result of the arrangement of the plurality of droplets satisfies an end condition while evaluating the arrangement of the plurality of droplets using a learned model that receives the arrangement of the plurality of droplets and outputs an evaluation value of the arrangement of the plurality of droplets.

10. A learned model, applied to a film forming method of forming a cured film by arranging a plurality of droplets of a curable composition on a substrate and curing a liquid film formed by connecting the plurality of droplets, of evaluating an arrangement of the plurality of droplets in the film forming method, wherein
the model is configured to receive the arrangement of the plurality of droplets and to output a merging probability between adjacent droplets among the plurality of droplets.

11. An information processing apparatus, applied to a film forming method of forming a cured film by arranging a plurality of droplets of a curable composition on a substrate and curing a liquid film formed by connecting the plurality of droplets, of deciding an arrangement of the plurality of droplets in the film forming method, the information processing apparatus comprising:
an updater configured to update the arrangement of the plurality of droplets until an evaluation result of the arrangement of the plurality of droplets satisfies an end condition while evaluating the arrangement of the plurality of droplets using a learned model that receives the arrangement of the plurality of droplets and outputs an evaluation value of the arrangement of the plurality of droplets.

12. A film forming method of forming a cured film of a curable composition on a substrate, comprising:
deciding an arrangement of a plurality of droplets of the curable composition in accordance with an information processing method defined in claim 1; and
forming the cured film by arranging the plurality of droplets on the substrate in accordance with the arrangement decided in the deciding and curing a liquid film formed by connecting the plurality of droplets.

13. An article manufacturing method of manufacturing an article, comprising:
deciding an arrangement of a plurality of droplets of a curable composition in accordance with an information processing method defined in claim 1;
forming a cured film by arranging the plurality of droplets on a substrate in accordance with the arrangement decided in the deciding and curing a liquid film formed by connecting the plurality of droplets; and
obtaining the article by processing the substrate on which the cured film has been formed.
